(19) United States
(12) Patent Application Publication
(10) Pub. No.: US 2011/0298785 A1
(43) Pub. Date: Dec. 8, 2011

(54) GATE SHIELDING FOR LIQUID CRYSTAL DISPLAYS

(75) Inventors: Ahmad Al-Dahle, Santa Clara, CA (US); Wei H. Yao, Fremont, CA (US)

(73) Assignee: APPLE INC., Cupertino, CA (US)

(21) Appl. No.: 12/792,291

(22) Filed: Jun. 2, 2010

(51) Int. Cl. G06F 3/038; G02F 1/1343; H01L 33/02

(52) U.S. Cl. 345/214; 257/59; 349/143; 257/E33.053

(57) ABSTRACT

Systems and methods for preventing parasitic capacitances within liquid crystal displays are provided. A display panel according to an embodiment may include, for example, a pixel with a pixel electrode and a transistor coupled to a gate line. Additionally, the pixel may include a shielding conductor interposed between the pixel electrode and the gate line. The shielding conductor may shield the pixel electrode from a parasitic capacitance with the gate line by causing a parasitic capacitance to form between the gate line and the shielding conductor instead of between the gate line and the pixel electrode.

### BACKGROUND

The present disclosure relates generally to electronic displays and, more particularly, to techniques for reducing parasitic capacitance in electronic displays.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

Flat panel displays, such as liquid crystal displays (LCDs), are commonly used in a wide variety of electronic devices, including such consumer electronics as televisions, computers, and handheld devices (e.g., cellular telephones, audio and video players, gaming systems, and so forth). Such display panels typically provide a flat display in a relatively thin package that is suitable for use in a variety of electronic goods. In addition, such devices typically use less power than comparable display technologies, making them suitable for use in battery-powered devices or in other contexts where it is desirable to minimize power usage.

LCD devices typically include a plurality of picture elements (pixels) arranged in a matrix to display an image that may be perceived by a user. Individual pixels of an

LCD device may variably permit light to pass when an electric field is applied to a liquid crystal material in each pixel, which may be generated by a voltage difference between a pixel electrode and a common electrode. A thin film transistor (TFT) may pass the voltage difference onto a pixel electrode when an activation voltage is applied to its gate and a data signal voltage is applied to its source. However, a parasitic capacitance between the pixel electrode and the gate line that supplies the gate activation voltage may interfere with the operation of the LCD device, producing visual artifacts or otherwise reducing the accuracy of the display. These problems may become more pronounced as LCDs increase in resolution, becoming more densely-packed.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Embodiments of the present disclosure relate to systems and methods for preventing parasitic capacitances within liquid crystal displays. For example, a display panel according to an embodiment may include, for example, a pixel with a pixel electrode and a transistor coupled to a gate line. Additionally, the pixel may include a shielding conductor interposed between the pixel electrode and the gate line. The shielding conductor may shield the pixel electrode from a parasitic capacitance with the gate line by causing a parasitic capacitance to form between the gate line and the shielding conductor instead of between the gate line and the pixel electrode.

### BRIEF DESCRIPTION OF THE DRAWINGS

Various aspects of this disclosure may be better understood upon reading the following detailed description and upon reference to the drawings in which:

FIG. 1 is a block diagram of components of an electronic device, in accordance with an embodiment;

FIG. 2 is a front view of a handheld electronic device, in accordance with an embodiment;

FIG. 3 is a perspective view of a notebook computer, in accordance with an embodiment;

FIG. 4 is a circuit diagram illustrating the structure of unit pixels of a display of the device of FIG. 1, in accordance with an embodiment;

FIG. 5 is a circuit diagram of a gate-shielded unit pixel of the display of the device of FIG. 1, in accordance with an embodiment; and

FIG. 6 is a flowchart describing an embodiment of a method for displaying images on the display of the device of FIG. 1 with reduced visual artifacts.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Present embodiments relate to techniques for preventing parasitic capacitances between electrical components within a display panel. In particular, an LCD display may activate rows of pixels by supplying an activation voltage to the gates of pixel transistors via gate lines, and may deactivate the rows of pixels by supplying a deactivation voltage (e.g., ground) to the gates of the pixel transistors via the gate lines. As the rows of pixels may be activated and deactivated very rapidly, a parasitic capacitance between the gate line and other components within the display panel may become more dominant and sensitive (e.g., more first order). To reduce the parasitic capacitances between the gate lines and image-signal-storing components of the display (e.g., the pixel electrodes), shielding conductors complementary to the gate lines may be disposed between the gate lines and such components. Thereafter, the parasitic capacitances may occur primarily between the gate lines and the shielding conductors instead of the image-signal-storing components of the display.

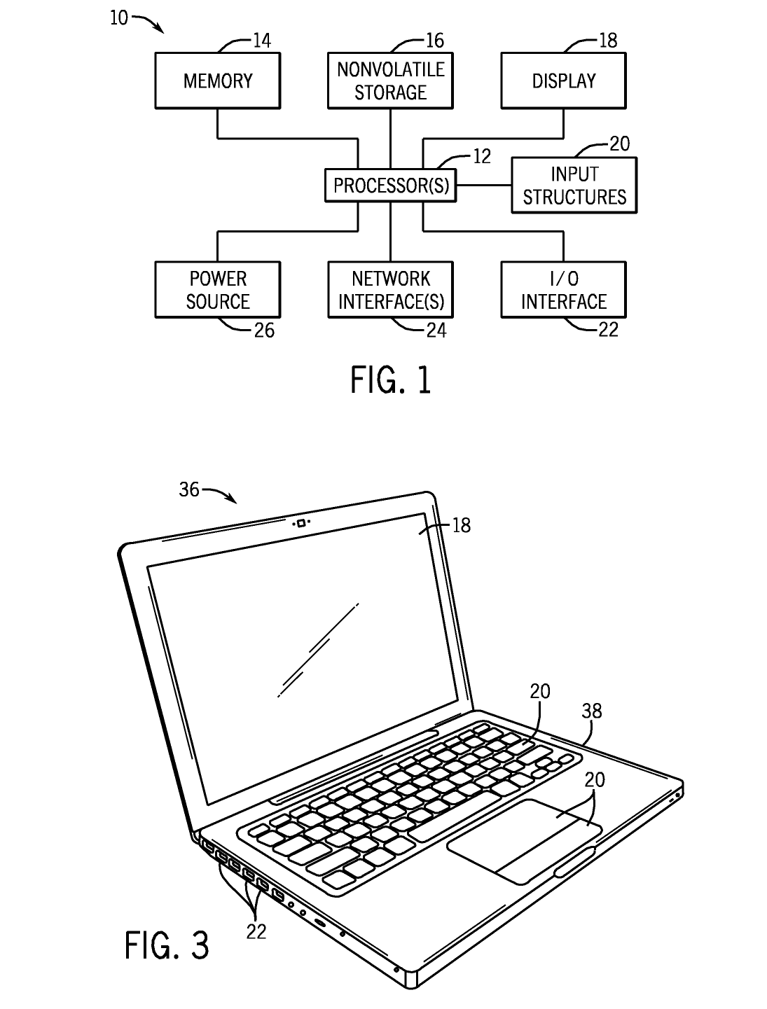

With the foregoing in mind, FIG. 1 represents a block diagram of an electronic device 10 employing a display 18 with gate-shielded pixels. Among other things, the electronic device 10 may include processor(s) 12, memory 14, nonvolatile storage 16, the display 18, input structures 20, an input/output (I/O) interface 22, network interface(s) 24, and/or a power source 26. In alternative embodiments, the electronic device 10 may include more or fewer components.

In general, the processor(s) 12 may govern the operation of the electronic device 10. In some embodiments, based on instructions loaded into the memory 14 from the nonvolatile storage 16, the processor(s) 12 may respond to user touch gestures input via the display 18. In addition to these instructions, the nonvolatile storage 16 also may store a variety of data. By way of example, the nonvolatile storage 16 may include a hard disk drive and/or solid state storage, such as Flash memory.

The display 18 may be a flat panel display, such as a liquid crystal display (LCD). As discussed in greater detail below, certain image-data-storing components (e.g., pixel electrodes) of the display 18 may be shielded to reduce parasitic capacitances between certain other components of the display 18 (e.g., gate lines). As a result, the image-data-storing components of the display 18 may less likely suffer from visual artifacts or reduced accuracy.

The display 18 also may represent one of the input structures 20. Other input structures 20 may include, for example, keys, buttons, and/or switches. The I/O ports 22 of the electronic device 10 may enable the electronic device 10 to transmit data to and receive data from other electronic devices 10 and/or various peripheral devices, such as external keyboards or mice. The network interface(s) 24 may enable personal area network (PAN) integration (e.g., Bluetooth), local area network (LAN) integration (e.g., Wi-Fi), and/or wide area network (WAN) integration (e.g., 3G). The power source 26 of the electronic device 10 may be any suitable source of power, such as a rechargeable lithium polymer (Li-poly) battery and/or alternating current (AC) power converter.

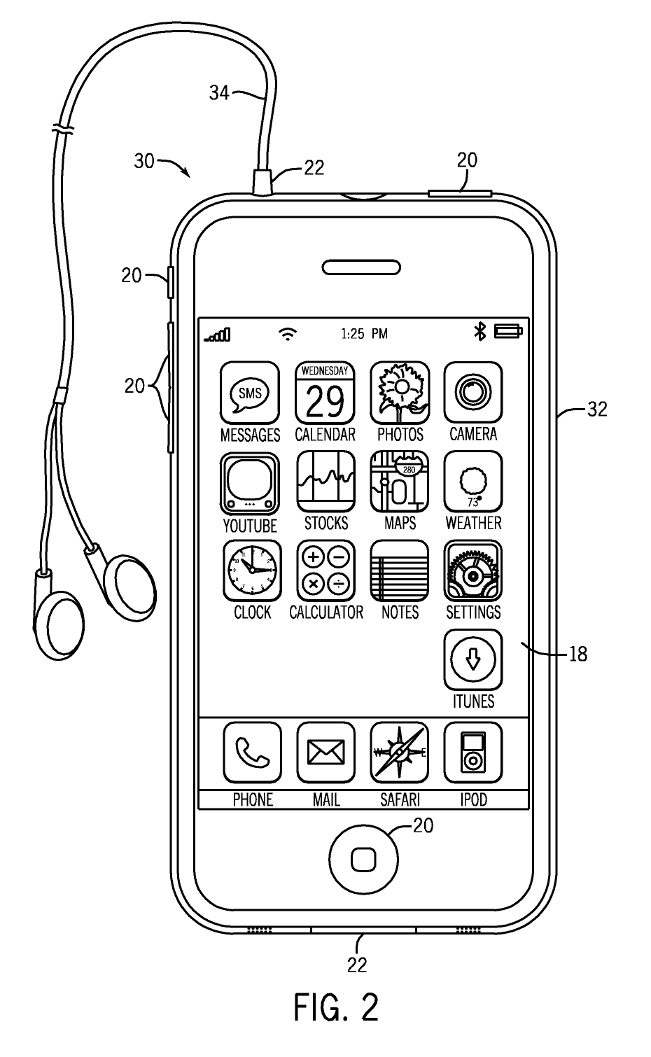

FIG. 2 illustrates an electronic device 10 in the form of a handheld device 30, here a cellular telephone. It should be noted that while the handheld device 30 is provided in the context of a cellular telephone, other types of handheld devices (such as media players for playing music and/or video, personal data organizers, handheld game platforms, and/or combinations of such devices) may also be suitably provided as the electronic device 10. Further, the handheld device 30 may incorporate the functionality of one or more types of devices, such as a media player, a cellular phone, a gaming platform, a personal data organizer, and so forth.

For example, in the depicted embodiment, the handheld device 30 is in the form of a cellular telephone that may provide various additional functionalities (such as the ability to take pictures, record audio and/or video, listen to music, play games, and so forth). As discussed with respect to the general electronic device of FIG. 1, the handheld device 30 may allow a user to connect to and communicate through the Internet or through other networks, such as local or wide area networks. The handheld device 30 also may communicate with other devices using short-range connections, such as Bluetooth and near field communication (NFC). By way of example, the handheld device 30 may be a model of an iPod® or iPhone® available from Apple Inc. of Cupertino, Calif.

The handheld device 30 may include an enclosure 32 or body that protects the interior components from physical damage and shields them from electromagnetic interference. The enclosure 32 may be formed from any suitable material, such as plastic, metal or a composite material, and may allow certain frequencies of electromagnetic radiation to pass through to wireless communication circuitry within handheld device 30 to facilitate wireless communication. The enclosure 32 may also include user input structures 20 through which a user may interface with the device. Each user input structure 20 may be configured to help control a device function when actuated. For example, in a cellular telephone implementation, one or more input structures 20 may be configured to invoke a “home” screen or menu to be displayed, to toggle between a sleep and a wake mode, to silence a ringer for a cell phone application, to increase or decrease a volume output, and so forth.

The display 18 may display a graphical user interface (GUI) that allows a user to interact with the handheld device 30. Icons of the GUI may be selected via a touch screen included in the display 18, or may be selected by one or more input structures 20, such as a wheel or button. The handheld device 30 also may include various I/O ports 22 that allow connection of the handheld device 30 to external devices. For example, one I/O port 22 may be a port that allows the transmission and reception of data or commands between the handheld device 30 and another electronic device, such as a computer. Such an I/O port 22 may be a proprietary port from Apple Inc. or may be an open standard I/O port. Another I/O port 22 may include a headphone jack to allow a headset 34 to connect to the handheld device 30.

In addition to the handheld device 30 of FIG. 2, the electronic device 10 may also take the form of a computer or other type of electronic device. Such a computer may include a computer that is generally portable (such as a laptop, notebook, and/or tablet computer) and/or a computer that is generally used in one place (such as a conventional desktop computer, workstation and/or servers). In certain embodiments, the electronic device 10 in the form of a computer may be a model of a MacBook®, MacBook® Pro, MacBook Air®, iMac®, Mac® mini, or Mac Pro® available from Apple Inc. In another embodiment, the electronic device 10 may be a tablet computing device, such as an iPad® available from Apple Inc. By way of example, a laptop computer 36 is illustrated in FIG. 3 and represents an embodiment of the electronic device 10 in accordance with one embodiment of the present disclosure. Among other things, the computer 36 includes a housing 38, a display 18, input structures 20, and I/O ports 22.

In one embodiment, the input structures 22 (such as a keyboard and/or touchpad) may enable interaction with the computer 36, such as to start, control, or operate a GUI or applications running on the computer 36. For example, a keyboard and/or touchpad may allow a user to navigate a user interface or application interface displayed on the display 18. Also as depicted, the computer 36 may also include various I/O ports 22 to allow connection of additional devices. For example, the computer 36 may include one or more I/O ports 22, such as a USB port or other port, suitable for connecting to another electronic device, a projector, a supplemental display, and so forth. In addition, the computer 36 may include network connectivity, memory, and storage capabilities, as described with respect to FIG. 1.

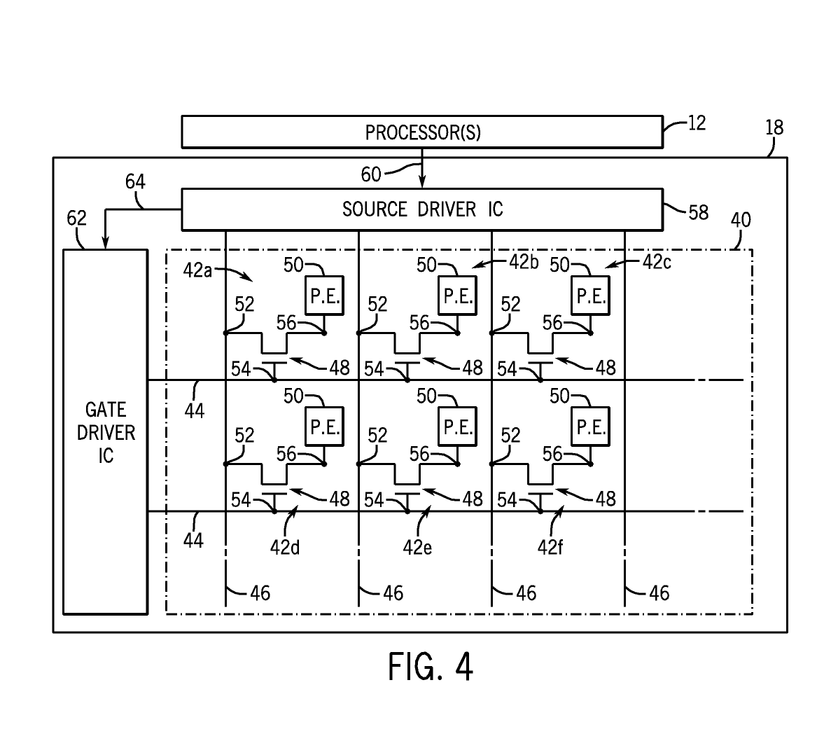

As noted briefly above, the display 18 represented in the embodiments of FIGS. 1-3 may be a liquid crystal display (LCD). FIG. 4 represents a circuit diagram of such a display 18, in accordance with an embodiment. As shown, the display 18 may include an LCD display panel 40 including unit pixels 42 disposed in a pixel array or matrix. In such an array, each unit pixel 42 may be defined by the intersection of rows and columns, represented here by the illustrated gate lines 44 (also referred to as “scanning lines”) and source lines 46 (also referred to as “data lines”), respectively. Although only six unit pixels, referred to individually by the reference numbers 42a-42f, respectively, are shown for purposes of simplicity, it should be understood that in an actual implementation, each source line 46 and gate line 44 may include hundreds or thousands of such unit pixels 42.

As shown in the present embodiment, each unit pixel 42 includes a thin film transistor (TFT) 48 for switching a data signal stored on a respective pixel electrode 50. In the depicted embodiment, a source 52 of each TFT 48 may be electrically connected to a source line 46 and a gate 54 of each TFT 48 may be electrically connected to a gate line 44. A drain 56 of each TFT 48 may be electrically connected to a respective pixel electrode 50. Each TFT 48 serves as a switching element which may be activated and deactivated (e.g., turned on and off) for a predetermined period based upon the respective presence or absence of a scanning signal at the gate 54 of the TFT 48.

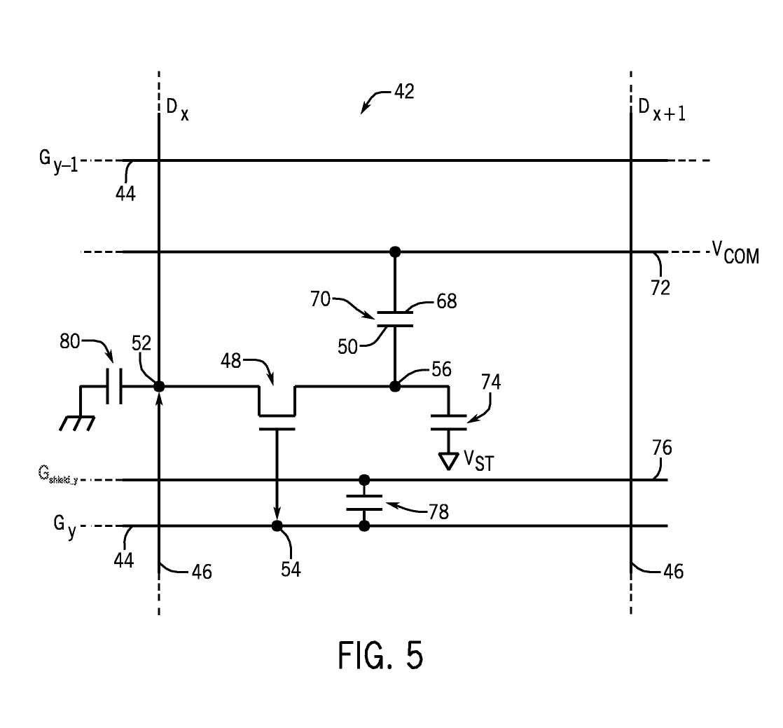

When activated, the TFT 48 may store the image signals received via a respective source line 46 as a charge upon its corresponding pixel electrode 50. The image signals stored by the pixel electrode 50 may be used to generate an electrical field between the respective pixel electrode 50 and a common electrode (not shown in FIG. 5). The electrical field between the respective pixel electrode 50 and the common electrode may alter the polarity of a liquid crystal layer above the unit pixel 42. The electrical field may align liquid crystals molecules within the liquid crystal layer to modulate light transmission. As the electrical field changes, the amount of light may increase or decrease. In general, light may pass through the unit pixel 42 at an intensity corresponding to the applied voltage (e.g., from a corresponding source line 46).

The display 18 also may include a source driver integrated circuit (IC) 58, which may include a chip, such as a processor or ASIC, that controls the display panel 40 by receiving image data 60 from the processor(s) 12 and sending corresponding image signals to the unit pixels 42 of the panel 40. The source driver IC 58 also may couple to a gate driver IC 62 that may activate or deactivate rows of unit pixels 42 via the gate lines 44. As such, the source driver IC 58 may send timing information, shown here by reference number 64, to gate driver IC 62 to facilitate activation/deactivation of individual rows of pixels 42. In other embodiments, timing information may be provided to the gate driver IC 62 in some other manner.

In operation, the source driver IC 58 receives image data 60 from the processor(s) 12 or a separate display controller and, based on the received data, outputs signals to control the pixels 42. For instance, to display image data 60, the source driver IC 58 may adjust the voltage of the pixel electrodes 50 one row at a time. To access an individual row of pixels 42, the gate driver IC 62 may send an activation signal (e.g., an activation voltage) to the TFTs 48 associated with the row of pixels 42, rendering the TFTs 48 of the addressed row conductive. The source driver IC 58 may transmit certain data signals to the unit pixels 42 of the addressed row via respective source lines 86. Thereafter, the gate driver IC 62 may deactivate the TFTs 48 in the addressed row by applying a deactivation signal (e.g., a lower voltage than the activation voltage, such as ground), thereby impeding the pixels 42 within that row from changing state until the next time they are addressed. The above-described process may be repeated for each row of pixels 42 in the panel 40 to reproduce image data 60 as a viewable image on the display 18. When an activation signal is sent across a gate line 44 to activate a row of pixels 42, or when the activation signal is withdrawn to deactivate the row of pixels, the rapid change in voltage could cause parasitic capacitances between the gate lines 44 and the pixel electrodes 50 of the pixels 42 in the row to become more dominant and sensitive (e.g., more first order). As such, the display panel 40 may include certain shielding to reduce such parasitic capacitances.

FIG. 5 represents a circuit diagram of an embodiment of a pixel 42 in greater detail. As shown, the TFT 48 is coupled to the source line 46 (Dₓ) and the gate line 44 (G_{y}). The pixel electrode 50 and the common electrode 68 may form a liquid crystal capacitor 70. The common electrode 68 is coupled to a common voltage line 72 that supplies the common voltage V_{COM}. The V_{COM} line 72 may be formed substantially parallel to the gate lines 44 or, in other embodiments, substantially parallel to the source lines 46.

In the present embodiment, the pixel 42 also includes a storage capacitor 74 having a first electrode coupled to the drain 56 of the TFT 48 and a second electrode coupled to a storage electrode line that supplies a storage voltage V_{ST}. In other embodiments, the second electrode of the storage capacitor 74 may be coupled instead to the previous gate line 44 (e.g., G_{y-1}) or to ground. The storage capacitor 74 may sustain the pixel electrode voltage during holding periods (e.g., until the next time the gate line 44 (G_{y}) is activated by the gate driver IC 62).

The gate line 44 (G_{y}) may have a complementary gate shielding line 76 (G_{shield}_{_{—}}_{y}) of the same or similar conductive material, which generally may be located between the gate line 44 (G_{y}) and the pixel electrode 50. The dominant parasitic capacitance may be a parasitic capacitance 78 between the gate line 44 (G_{y}) and the gate shielding line 76 (G_{shield y}), rather than between the gate line 44 (G_{y}) and the pixel electrode 50. Thus, when the voltage of the gate line 44 (G_{y}) changes rapidly (e.g., during activation or deactivation of the unit pixel 42), the voltage may be much less affected by a parasitic capacitance between the gate line 44 (G_{y}) and the pixel electrode 50. In some embodiments, the gate shielding line 76 may cause the pixel electrode 50 to have a significantly reduced parasitic capacitance with the gate line 44.

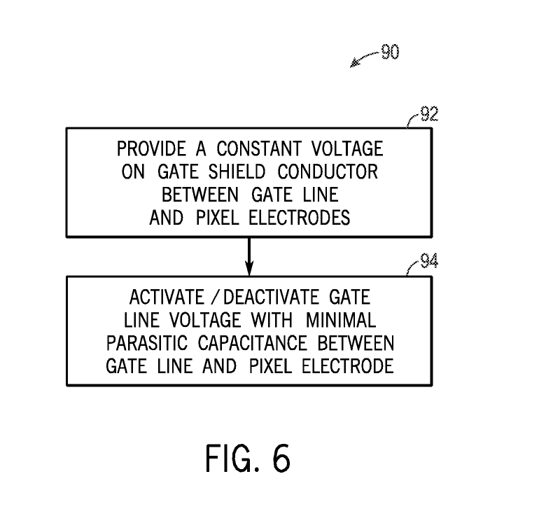

One embodiment of a method for operating the display panel 40 in a manner that reduces parasitic capacitances appears in flowchart 90 of FIG. 6. In general, while a gate line 44 may be supplied with a variable voltage (e.g., either an activation voltage or a deactivation voltage at any point in time), a corresponding gate shielding line 76 may be supplied with a constant voltage (block 92). In particular, in certain embodiments, such a gate shielding line 76 may be supplied with a constant voltage that is lower than the activation voltage, higher than the activation voltage, equal to the activation voltage, or equal to an average value of the data signals currently provided to the display panel 18 or the currently addressed row of pixels of the display panel. In some embodiments, such a gate shielding line 76 may be tied to ground.

Thereafter, the gate driver IC 60 may activate and deactivate rows of pixels 42 (block 94). Because certain parasitic capacitances between the gate lines 44 and corresponding gate shielding lines 76 (e.g., parasitic capacitance 78) may be present, parasitic capacitances between the pixel electrodes 50 of the pixels 42 and the gate lines 44 may be significantly reduced. Thus, when the rows of pixels 42 are activated and deactivated, the voltages of the pixel electrodes 50 may experience much less change due to parasitic capacitances between the pixel electrodes 50 and the gate lines 44.

In alternative embodiments, gate shielding lines 76 may be supplied with a voltage that varies between ground and another voltage (e.g., in some embodiments, a voltage lower than the activation voltage) at a lower frequency than the frequency at which the activation voltage is switched on or off. For such embodiments, the frequency of the voltage change on the gate shielding lines 76 may be low enough such that despite any parasitic capacitances between the gate shielding lines 76 and the pixel electrodes 50, the pixel electrodes 50 are largely unaffected. That is, the changing voltages of the gate shielding lines 76 may not noticeably alter pixel electrode 50 performance (e.g., the accuracy of the pixel electrodes 50 may be substantially undetectable to the naked eye) due to such parasitic capacitances between the gate shielding lines 76 and the pixel electrodes 50. In general, for such embodiments, a gate shielding line 76 may be grounded to reduce power consumption when a corresponding gate line 44 is not about to activate a row of pixels 42. Thereafter, the gate shielding line 76 may gradually increase in voltage to reach the desired voltage (e.g., a voltage lower than the activation voltage) at the point when the gate line 44 activates and deactivates the row of pixels 42, before gradually decreasing back to ground.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

What is claimed is:

1. A display panel comprising:
a pixel that includes:
a pixel electrode;
a transistor having a drain coupled to the pixel electrode, a source coupled to a data line, and a gate coupled to a gate line, wherein the transistor is configured to pass a data signal from the data line to the pixel electrode upon receipt of an activation signal from the gate line; and
a shielding conductor interposed between the pixel electrode and the gate line, wherein the shielding conductor is configured to shield the pixel electrode from a parasitic capacitance with the gate line by causing a parasitic capacitance between the gate line and the shielding conductor instead of between the gate line and the pixel electrode.

2. The display panel of claim 1, wherein the shielding conductor is configured to carry a constant voltage.

3. The display panel of claim 1, wherein the shielding conductor is configured to carry a voltage equal to an activation voltage supplied by the gate line.

4. The display panel of claim 1, wherein the shielding conductor is configured to carry a voltage lower than an activation voltage supplied by the gate line.

5. The display panel of claim 1, wherein the shielding conductor is configured to carry a voltage higher than an activation voltage supplied by the gate line.

6. The display panel of claim 1, wherein the shielding conductor is grounded.

7. The display panel of claim 1, wherein the shielding conductor is configured to carry a voltage that varies more slowly than an activation voltage supplied by the gate line.

8. A system comprising:
a processor configured to generate display signals;
a display configured to generate pixel activation signals and pixel data signals based on the display signals, wherein display is configured to provide the pixel activation signals and pixel data signals to pixels of the display via signal conductors, and wherein the pixels of the display comprise shielding conductors interposed between pixel electrodes of the pixels and a subset of the signal conductors to shield the pixel electrodes voltage changes due to parasitic capacitances between the signal conductors and the pixel electrodes when the pixel activation signals or the pixel data signals are provided to the pixels.

9. The system of claim 8, wherein the shielding conductors are substantially parallel to the subset of the signal conductors.

10. The system of claim 8, wherein the shielding conductors are substantially equidistant between the subset of the signal conductors and the pixel electrodes.

11. A display panel comprising:
a plurality of pixel electrodes configured to store data signals;
a plurality of data signal carriers configured to carry the data signals;
a plurality of transistors corresponding to the plurality of pixel electrodes and coupled thereto, wherein the plurality of transistors is configured to pass the data signals from the plurality of data signal carriers to the plurality of pixel electrodes when activation signals are applied to gates of the plurality of transistors;
a plurality of gate lines configured to provide the activation signals to the gates of the plurality of transistors; and
a plurality of shielding lines corresponding to the plurality of gate lines, wherein the plurality of shielding lines are interposed between subsets of the plurality of pixel electrodes and the gate lines, wherein the plurality of shielding lines is configured to shield the plurality of pixel electrodes from parasitic capacitances from the plurality of gate lines.

12. The display panel of claim 11, wherein each of the plurality of shielding lines is configured to shield one of the subsets of the plurality of pixel electrodes from parasitic capacitances from one of the plurality of gate lines.

13. The display panel of claim 11, wherein the plurality of shielding lines is configured to carry a substantially constant voltage.

14. The display panel of claim 11, wherein the plurality of shielding lines is configured to carry a voltage approximately equal to an average value of the data signals.

15. The display panel of claim 11, wherein the plurality of shielding lines is configured to carry a first voltage that varies less often than a second voltage carried by the plurality of gate lines.

16. A method comprising:
supplying an activation signal to a plurality of pixels via a gate line;
supplying a deactivation signal to the plurality of pixels via the gate line; and
shielding pixel electrodes of the plurality of pixels from parasitic capacitances between the pixel electrodes and the gate line when the activation signal and deactivation signal are supplied using a shielding conductor configured to cause a parasitic capacitance between the gate line and the shielding conductor instead of between the gate line and the pixel electrodes of the plurality of pixels.

17. The method of claim 16, wherein the pixel electrodes of the plurality of pixels are shielded by the shielding conductor, wherein the shielding conductor is substantially parallel to the gate line.

18. The method of claim 16, comprising supplying a constant voltage to the shielding conductor.

19. The method of claim 16, comprising supplying a voltage lower than the activation signal and greater than the deactivation signal to the shielding conductor.

20. The method of claim 16, comprising supplying a low frequency voltage to the shielding conductor, wherein the low frequency voltage has a frequency sufficiently low to substantially preclude parasitic capacitances that noticeably alter pixel electrode performance between the shielding conductor and the pixel electrodes of the plurality of pixels.
